(19) United States
(12) Patent Application Publication
(10) Pub. No.: US 2022/0187376 A1
(43) Pub. Date: Jun. 16, 2022

(54) Method and Device for Predicting a State of Health of an Energy Storage System

(71) Applicant: Robert Bosch GmbH, Stuttgart (DE)

(72) Inventors: Christian Simonis, Leonberg (DE); Stefan Schindler, Bietigheim-Bissingen (DE)

(21) Appl. No.: 17/550,590

(22) Filed: Dec. 14, 2021

(30) Foreign Application Priority Data
Dec. 15, 2020 (DE) 10 2020 215 890.8

(51) Int. Cl. G01R 31/367; G01R 31/392; G01R 31/00

(52) U.S. Cl. CPC G01R 31/367; G01R 31/007; G01R 31/392

(57) ABSTRACT

The disclosure relates to a method for determining a predicted state-of-health curve of device batteries in battery-powered machines. The method comprises: (i) providing data points of a state-of-health curve/trajectory of a device battery, the data points indicating a state of health via an aging time point of the device battery, the state-of-health curve/trajectory indicating a progression of a state of health up to a current state of health; (ii) determining a database of a plurality of data points within a time period which ends at the current aging time point, the database being determined such that a residual between the model function and the data points is minimized by fitting the model function; (iii) extrapolating the plurality of data points of the database by parameterizing the model function; and (iv) determining a predicted state of health using the parameterized model function at a predetermined prediction time point.

This application claims priority under 35 U.S.C. §119 to application no. DE 10 2020 215 890.8, filed on Dec. 15, 2020 in Germany, the disclosure of which is incorporated herein by reference in its entirety.

### TECHNICAL FIELD

The present disclosure relates to energy storage systems, in particular battery-powered machines such as electrically drivable motor vehicles, in particular electric vehicles or hybrid vehicles, and further relates to measures for determining a state of health (SOH) of an energy storage device for a battery-powered machine.

### BACKGROUND

Battery-powered machines and devices, in particular electrically drivable motor vehicles, are supplied with power with the aid of energy storage devices, in particular device batteries, for example, a vehicle battery. In the following, energy storage devices of device batteries and vehicle batteries will be discussed. However, the term “energy storage device” is intended to comprise all storage systems for electrical energy which provide electrical energy based on an electrochemical reaction. In a broader sense, fuel cells may also be considered for this purpose, which, unlike batteries, are continuously supplied with chemical energy.

The device battery supplies electrical energy for operating machine systems. The state of health of the device battery deteriorates appreciably over the course of its lifetime, resulting in a decreasing maximum storage capacity. An extent of the aging of the device battery is a function of an individual load on the device battery, i.e. the usage behavior of a user, and the type of the device battery.

Although a physical aging model can be used to determine the current state of health based on historical operating variable curves, this model is often highly inaccurate. This inaccuracy of the conventional aging model makes it difficult to predict the state-of-health curve. However, the prediction of the state-of-health curve of the device battery is an important technical variable, since it enables an economic evaluation of a residual value of the device battery.

In addition, for battery types which were not extensively measured prior to commissioning, no state-of-health models are available via which the battery control unit can indicate a state of health. In particular, both details about the cell chemistry and the battery structure or its interconnection are unknown, and thus the pure operating variables of the battery are the only reliable values on the basis of which a state of health can be determined.

### SUMMARY

According to the present disclosure, a method is provided for determining a state-of-health trajectory of a device battery in a battery-powered machine, in particular of an electrically drivable motor vehicle, and a device and a battery-powered machine are provided.

Further embodiments are specified in the embodiments.

According to a first aspect, a computer-implemented method is provided for determining a predicted state-of-health curve of one or a plurality of device batteries in battery-powered machines, in particular in electrically drivable motor vehicles, comprising the following steps:
Providing data points of a state-of-health curve of a device battery or trajectory points of a state-of-health trajectory for a plurality of device batteries in a central unit, wherein the data points or the trajectory points respectively indicate a state of health via an aging time point of the device battery, wherein the state-of-health curve or the state-of-health trajectory indicates a progression of a state of health up to a current state of health;
Determining a database of a plurality of data points/trajectory points within a time period which ends at the current aging time point, wherein the database is determined in such a way that the residual between the model function and the data points/trajectory points is minimized by fitting the model function;
Extrapolating the plurality of data points/trajectory points by parameterizing the model function, in particular a linear model function;
Determining a predicted state of health with the aid of the parameterized model function.

Furthermore, a database of a plurality of data points/trajectory points may be determined by selecting the time period starting from a time point at which a second derivative of one of the data points/trajectory points last exceeds the magnitude of a predetermined curvature threshold value.

In the case of unknown battery types of device batteries in battery-powered machines, it may not be possible under some circumstances for the respective battery control unit to determine or provide information about the state of health of the respective device battery. Only operating variables such as battery voltage, battery current, battery temperature, and state of charge can be read out in these cases. Although the respective state of health of a device battery can be determined by observing the battery behavior during a charging or discharging process, these methods are inaccurate and are not suitable for estimating a remaining lifetime. Even in the case of batteries of a known battery type, it is not possible to go below levels of accuracy of 5% in this way, since said levels of accuracy are essentially a function of the usage-related operating profile, for example the range of the state of charge, an average temperature range of the battery operation, and the like.

The use of fleet data from battery-powered machines comprising device batteries of unknown battery types presents an even greater challenge for determining the state of health, since operating variables are influenced by different load profiles, user profiles, and by serial control of the device batteries.

The above method now provides for carrying out an evaluation, on the basis of operating data of one or a plurality of device batteries of unknown battery type, in a central unit external to the device, via which the curve of the state of health for the relevant battery type can be determined from an evaluation of time curves of operating variables for determining the state of health.

For modeling the state of health, a distinction may be made between physical and data-driven methods. Physical methods map the aging behavior via a causal physical description of the underlying aging mechanisms. In data-based methods, the progression of the state of health is predicted from measurements and observations. Data-based methods are widely used in practice, as they constitute efficient data processing with an implicit description of the aging mechanisms and underlying chains of reaction. The advantage of data-based methods with respect to the prior art is that the method device batteries of unknown type, for which no electrochemical parameterization is available, can also be quantified on an ongoing basis with respect to their state of health. The method also makes it possible to improve the state-of-health trajectory as soon as new data points have been determined for the device batteries of the battery-powered machines under consideration. The state-of-health trajectory may be determined by successive if a sufficient number of data points are available.

The reliability or accuracy of simple data-based methods, for example linear regression, is limited in particular by the fact that the state of health generally exhibits a highly nonlinear progression over time. On the one hand, this complicates the choice of the optimal database of data points which are considered for prediction, and on the other hand, the choice of a suitable prediction horizon of the extent to which the state of health can be reliably predicted into the future. In the case of non-physically based state-of-health models which predict a state of health based on historical data points, the prediction is often carried out by means of linear extrapolation. In this case, it is crucial which of the data points are taken into consideration for linearization.

The curve of the state of health of device batteries is highly nonlinear for older device batteries, in particular toward the end of their service life, and the gradient is particularly steep. Therefore, when selecting the data points to be taken into consideration, there is the difficulty of choosing the data domain in such a way that the state-of-health model best describes the current trend within the applicable limits, while also specifying a plausible prediction along a state-of-health trajectory.

In addition, it is necessary to specify a prediction horizon as an aging time point of the relevant device battery up to which a sufficiently reliable prediction of the state of health is possible by evaluating historical data points.

In order to enable a standardized prediction of the state of health which can be transferred to any battery format, it is necessary to determine a generally applicable criterion for the selection of the data points or trajectory points to be considered for the prediction and selection of the prediction horizon. In this respect, the above method provides for selecting the optimal database for the prediction of the state of health and the prediction horizon for naive predictions, i.e., simple extrapolation according to a predefined model function via a systematic mathematical analysis of the state-of-health trajectory based on historical data.

For this purpose, the above method provides for an applicability to any arbitrary aging curves, which are by nature always monotonic, regardless of the methods used for determining the aging curves, which may be specified as a state-of-health trajectory or as a set of data points. The data points and/or the state-of-health trajectory may be determined using physical and/or hybrid models for estimating the state of health of batteries of any battery chemistries and formats.

Especially for short- and medium-term prediction horizons, the above method constitutes a suitable method for estimating the reliability of a prediction of a future state of health and for determining a remaining lifetime, without further prior knowledge about the underlying aging behavior.

The above method is based on a database in which states of health of a device battery or of a plurality of device batteries of any, not necessarily identical, device battery type have been recorded up to a current aging time point. The recorded data points may now be further processed directly or combined into a common state-of-health trajectory in order to eliminate outliers and to smooth the state-of-health values.

For the recorded data points/trajectory points of a state-of-health curve, a database is determined in such a way that a model function fitted to the data points/trajectory points of the database is determined as a function of a resulting residual. In particular, the residual is not to exceed a limit value. For this purpose, for example, the second derivatives may be formed in order to determine a smoothed shape of the curvatures of the recorded state-of-health curve with the aid of further filter functions. The second derivatives at the respective aging time points are checked point by point, i.e. at the relevant aging time points, starting from the last available (most recent) data point/trajectory point into the past, via a threshold value comparison to determine whether they exceed a certain threshold value. The database of data points/trajectory points to be taken into consideration for the extrapolation is obtained from the data point of which the associated second derivative (curvature) exceeds the predetermined threshold value, up to the current aging time point. This ensures that the database for the prediction comprises exactly that part of the state-of-health curve in which the slope is sufficiently flat, so that the model function of the naive prediction sufficiently describes the behavior of the state-of-health curve in the selected data domain and continues as steadily as possible in the extrapolation domain.

With the aid of the predicted model function, a point in time may be predicted at which a particular state of health is reached which can be predicted with a sufficiently high level of quality based on the model. In particular, the end of life of the device battery or a remaining lifetime of the device battery, based on the model function, are relevant here. By means in particular of linear extrapolation, it is now possible to determine a remaining lifetime of the relevant device battery for which the state of health falls below a predetermined threshold state of health.

In addition, an optimal prediction horizon may be determined based on the identified database of data points/trajectory points. Two predictions are carried out with an increasing prediction horizon until the deviation ASOH of the predicted state-of-health values exceeds a predefined limit value. The predictions include a naive prediction, which may, for example, comprise a linear extrapolation, and a prediction/extrapolation at constant curvature resulting from the curve of the second derivatives in the selected data domain. The extrapolation based on the curve of the second derivatives may, for example, be a function of the weighted average or median value of the second derivatives in the domain of the database.

A prediction horizon may be determined as a time point up to which a predetermined prediction certainty exists, wherein the time point is determined as a time point at which a deviation between the model function and a further model function which extrapolates a further predicted curve based on the curvature and, if applicable, the slope of the plurality of data points/trajectory points of the database at the current aging time point, achieves the predetermined prediction certainty. In other words, the time point is determined in that an absolute or relative deviation between the model function and the extrapolation based on the curvature of the trajectory in the domain of the database, the predetermined prediction certainty.

In particular, the predicted state of health at the time point of the prediction horizon may be determined as a weighted average value of the model value of the model function and the model value of the further model function.

The curvature determined from the second derivatives and the last slope value of the state-of-health curve in the selected data domain is now extrapolated synthetically. It is thereby ensured that the prediction horizon is selected in exactly such a way that the naive prediction best reflects the behavior of the prediction based on constant curvature until the predefined limit value is reached.

For predicting the aging behavior, a predicted state of health may now be provided which is based on the optimal prediction horizon resulting from the previously determined optimal database, and which results as a weighted average value of the naive and curvature-based prediction. Thus, depending on the weighting, either the naive or curvature-based prediction is given greater importance with respect to the predicted state of health.

The weightings, which indicate how strongly, for example, the linear prediction is to be weighed, and, for example, how strongly the prediction with constant curvature is to be weighted, may be determined with the aid of a weighting model. The weighting model may be optimized as a self-learning system via clustering methods based on similarity conditions for each battery, and may be learned over large amounts of data.

Furthermore, the predicted state of health may be signaled at the time point of the prediction horizon.

The predicted state of health may be compared by the vehicle manufacturer or battery manufacturer with its technical specification in order to carry out continuous lifetime monitoring of the device battery. Furthermore, the predicted state of health is relevant for a usage certificate of the device battery, as it is associated with the residual value of the device battery.

Furthermore, the degradation behavior of a plurality of device batteries in a fleet may be compared in order to make statements about the series dispersion and the aging behavior via statistical quantile evaluations. The usage behavior of device batteries from particularly critical quantiles may be optimized via measures for extending the lifetime of the device battery, for example, with the aid of an optimized charging curve or reduced stress factors.

Furthermore, the method may be carried out entirely or partially in a central unit external to the device which has a communication link to a plurality of battery-powered machines.

According to a further aspect, a device is provided for determining a predicted state-of-health curve of one or a plurality of device batteries of an identical battery type in battery-powered machines, in particular in electrically drivable motor vehicles, wherein the device is configured to:
Receive data points of a state-of-health curve of a device battery or of trajectory points of a state-of-health trajectory for a plurality of device batteries in a central unit, wherein the data points or the trajectory points respectively indicate a state of health via an aging time point of the device battery, wherein the state-of-health curve or the state-of-health trajectory indicates a progression of a state of health up to a current state of health;
Determine a database of a plurality of data points/trajectory points within a time period which ends at the current aging time point, wherein the database is determined in such a way that the residual between the model function and the data points/trajectory points is minimized by fitting the model function;
Extrapolate the plurality of data points/trajectory points by parameterizing the model function, in particular a linear model function;
Determine a predicted state of health with the aid of the parameterized model function.

### BRIEF DESCRIPTION OF THE DRAWINGS

Exemplary embodiments will be explained in greater detail with reference to the appended drawings. The following are shown:

FIG. 1 shows a schematic depiction of a system for providing driver- and vehicle-specific operating variables relating to the operation of a vehicle battery of vehicles in a vehicle fleet to a central unit;

FIG. 2 shows a flow chart for illustrating a method for determining a state-of-health trajectory for a vehicle battery in a motor vehicle of unknown battery type;

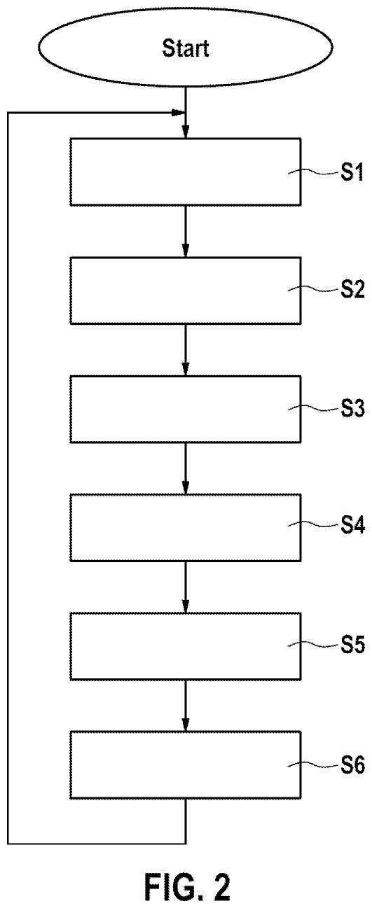

FIG. 3 shows a diagram comprising data points or trajectory points and an extrapolation starting from a current aging time point T, for different databases;

FIG. 4 shows a depiction of a state-of-health trajectory for exemplary data points along with first and second derivatives of the data points; and

FIG. 5 shows examples of predicted curves of the first prediction and the second prediction for illustrating the determination of the prediction horizon.

### DETAILED DESCRIPTION

In the following, the method according to the present disclosure will be described, using vehicle batteries as device batteries in a motor vehicle, as a battery-powered device or battery-powered machine. This example is representative of a large number of stationary or mobile battery-powered machines and devices having a network-independent power supply, for example, vehicles (electric vehicles, pedelecs, etc.), plants, machine tools, household devices, IOT devices, building power supplies, aircraft, in particular drones, autonomous robots, and consumer electronics devices, in particular mobile telephones, and the like, which are connected to a central unit (cloud) via a corresponding communication link (for example, LAN, Internet).

The method is used for predicting a state-of-health curve of one or a plurality of device batteries of the same type, wherein the latter case will be described in greater detail below.

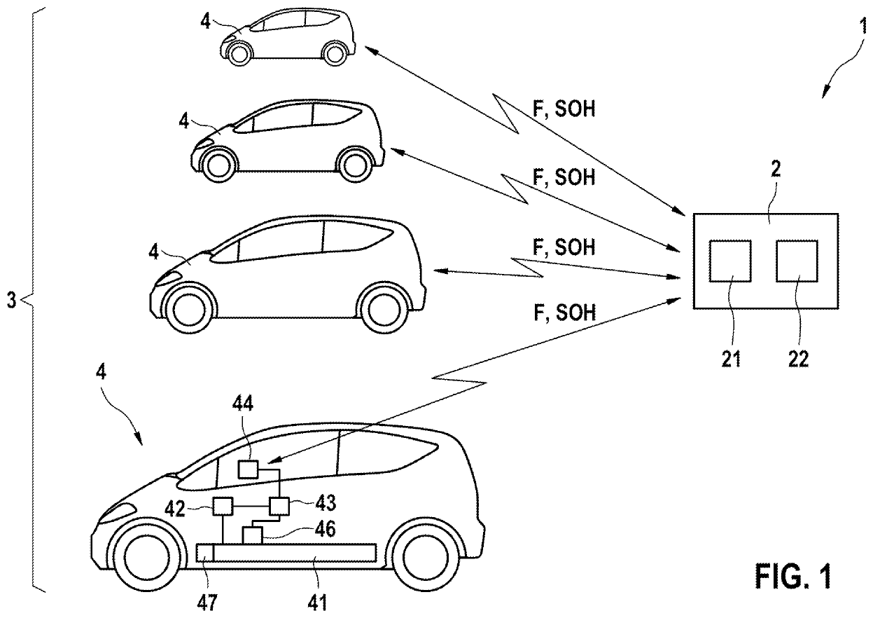

FIG. 1 shows a system 1 for collecting fleet data in a central unit 2 for creating, operating, and evaluating a state-of-health model, which may be configured as a reference model or observer model. The reference model or observer model is used for determining a state-of-health value of the vehicle battery in a motor vehicle, and can thus indicate a state-of-health curve when determining state-of-health values at different points in time. FIG. 1 shows a vehicle fleet 3 comprising a plurality of motor vehicles 4. In the central unit 2, a state-of-health trajectory for the vehicle batteries of motor vehicles 4 of the vehicle fleet 3 may be determined based on the fleet data, by determining a most likely curve of the state of health from the data points. The state-of-health trajectory indicates a trajectory point for different aging time points, said trajectory point indicating an estimated state of health of the vehicle battery for the particular aging time point. Alternatively, the state-of-health model may also be configured as a physical (electrochemical) model, in particular in conjunction with a trainable data-based correction component, for example, in the form of a machine-learning model, for example, a neural network or the like.

One of the motor vehicles 4 is depicted in greater detail in FIG. 1. The motor vehicles 4 respectively comprise a vehicle battery 41 as a device battery, an electrical drive motor 42, and a control unit 43. The control unit 43 is connected to a communication module 44 which is suitable for transmitting data between the respective motor vehicle 4 and the central unit 2 (a so-called cloud). The control unit 43 is connected to a sensor unit 45 which comprises one or a plurality of sensors in order to acquire operating variables continuously.

The motor vehicles 4 transmit the operating variables F to the central unit 2, said operating variables at least indicating variables on which the state of health of the vehicle battery depends. In the case of a vehicle battery 41, the operating variables F may indicate an instantaneous battery current, an instantaneous battery voltage, an instantaneous battery temperature, and an instantaneous state of charge (SOC), as well as the pack level, module level, and/or cell level. The operating variables F are acquired in a fast time raster of 0.1 Hz to 100 Hz, depending on the signal type, and may be transmitted regularly to the central unit 2 in uncompressed and/or compressed form. For example, the time series may be transmitted to the central unit 2 in blocks at an interval of 10 minutes to several hours.

The central unit 2 comprises a data processing unit 21 in which the method described below can be carried out, and a database 22 for storing states of health having respectively associated aging time points of the vehicle batteries 41 of a plurality of vehicles 4 of the vehicle fleet 3.

The state of health (SOH) is the key variable for indicating a remaining battery capacity or remaining battery charge. The state of health constitutes a measure of the aging of the vehicle battery or a battery module or a battery cell, and may be expressed as a capacity retention rate (SOH-C) or as an increase in internal resistance (SOH-R). The capacity retention rate SOH-C is indicated as the ratio of the measured instantaneous capacity to an initial capacity of the fully charged battery. The relative change in the internal resistance SOH-R increases with increasing aging of the battery.

In the central unit 2, a state-of-health trajectory may be determined with the aid of a method which is in particular completely or partially data-based. The state-of-health trajectory is intended to characterize the vehicle battery of unknown battery type, i.e. having unknown electrochemical properties and unknown parameters of the battery, in order to be able to indicate or predict a state of health in each case for aging time points of the vehicle batteries. State-of-health values for the vehicle batteries of unknown battery type are determined based on the time curves of the corresponding operating variables, by evaluating the battery behavior during a charging and/or discharging process, for example, by means of the coulomb counting method which is known per se.

The state-of-health value is associated with the aging time point of the relevant vehicle battery 41, thereby determining a data point for creating a state-of-health curve model.

The method described below is carried out in the central unit 2 and makes it possible to predict a state of health for one or a plurality of vehicle batteries at a future aging time point. The aging time point is to be chosen as a time point at which a sufficiently reliable prediction of the aging behavior is possible. The method may be implemented in the control unit 21 of the central unit 2 as software and/or hardware.

In step S1, operating variables F as described above are transmitted from the vehicles 4 of the vehicle fleet 3 to the central unit 2 at regular time intervals. Thus, time curves of the operating variables F for a plurality of vehicle batteries 41 are available for evaluation in the central unit 2. The evaluations take place regularly according to predetermined evaluation time periods, so that time curves of the operating variables F which have already been evaluated are not evaluated repeatedly. A typical value for the evaluation period is one week.

In step S2, the time curves of the operating variables F in the previous evaluation period are filtered for each of the vehicle batteries 41. In particular, the time curves of the operating variables F may be checked to determine whether measurement outliers are present. In addition, the time curves may be filtered in order to eliminate measurement outliers. The data preparation of the operating variables is used to filter out short-term measurement errors which occur, for example, due to an interference effect (EMC), in order to improve the quality of a subsequent determination of the state-of-health value. Low-pass filters, smoothing methods, or the like, and suitable outlier elimination methods, may be considered as filtering methods.

For example, a plausibility check is performed in a rule-based manner on domain knowledge (for example, if the current is positive, the SOC must not decrease). Furthermore, a comparison and an evaluation may be made with previous, typical state variables and utility patterns in order to perform an anomaly evaluation. In addition, sigma clipping may be used to evaluate or correct the residual if a limit value is exceeded, in particular after a trend function has been calculated out, for example, via a nonlinear functional (for example, via an ARIMA model). This results in a smoothing of the time curves of the operating variables, since outliers are eliminated. Subsequently, a PT1 element or a Butterworth filter may also be used for smoothing the curves using signal technology.

In step S3, a determination of the state-of-health value is carried out according to a reference or observer model, based on the time series of the operating variables F. Said model provides for determining the state-of-health value from observation or measurement of the operating variables as a capacity retention rate (SOH-C) or based on an internal change in resistance (SOH-R).

For example, a state-of-health value based on the capacity retention rate (SOH-C) may be determined based on a coulomb counting method. In addition, the time curves of the operating variables are used to detect that a charging process is being carried out. The charging process may be detected, for example, if a constant current is supplied, starting from a state of full discharge of the vehicle battery 41 (this may be detected if a final discharge voltage has been reached). The charging process may thus be determined based on a constant current flow into the vehicle battery 41. If the charging process has been performed up to a full charge, the total amount of charge delivered to the vehicle battery may be determined by integrating the current flow into the vehicle battery. This maximum amount of charge may be associated with a state-of-health value by means of comparison with a nominal charging capacity of the vehicle battery 41. Partial charges having a specific charging delivery and corresponding measurements of the cell voltages before and after the partial charging may also be evaluated in order to determine the state-of-health value based on the capacity retention rate.

Furthermore, the coulomb counting may also be carried out in the case of discharge processes, for example, during a driving cycle, by determining an amount of charge flowing out and by evaluating the cell voltages before and after the partial charging. If a state-of-health value SOH-C determined on the capacity retention rate is determined in this way, said value is assigned with a time stamp which corresponds to an aging time point of the relevant vehicle battery, in order to form a corresponding data point.

Alternatively, a state-of-health value may also be determined as an internal resistance-based state of health SOH-R. In this case, at the start of the charging process, a AU/AI is determined as the quotient of the change in battery voltage to the change in battery current, and a state of health SOH-R is associated with it in a manner known per se. The state-of-health value thereby determined may be associated with the aging time point of the relevant vehicle battery 41 in order to form a corresponding data point.

Both the state-of-health values SOH-C based on the capacity retention rate and the state-of-health values SOH-R based on the change in internal resistance may be used for all vehicle batteries correspondingly together or separately as new data points for determining the state-of-health trajectory.

Thus, state-of-health values may be provided at different aging time points of the device battery. State-of-health values of a single device battery or a plurality of device batteries may be used as a database. The data points form a state-of-health curve up to a current aging time point, or trajectory points of a state-of-health trajectory up to the current aging time point. The state-of-health values may be tracked as observations by evaluating the operating variables, for example with the aid of a coulomb counting method or by measuring the change in internal resistance in in a manner known per se.

Alternatively, the state-of-health values may also be determined with the aid of a physical (electrochemical process) model or a hybrid model having a data-based portion as model values.

If a prediction of the state of health is to be made at a particular evaluation time point (current aging time point at which the most recent state-of-health value is present), the optimal database is first determined in step S4.

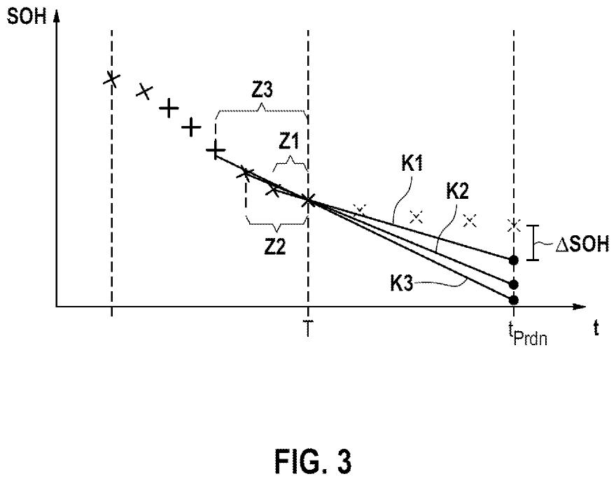

The determination of an optimal database is important, since an extrapolation of a model function for determining a state of health depends considerably on the parameterization of the model function based on the selection of the data points/trajectory points, for example as depicted in the diagram of FIG. 3. FIG. 3 shows data points or trajectory points as crosses. When extrapolating from a current aging time point T, different linear curves K1, K2, K3 of a model function result for extrapolation, depending on the database Z1, Z2, Z3 (time period in which the data points are used for parameterization) which is taken into consideration. These extrapolated curves exhibit an increasing deviation from the actual model values of the model function (indicated by crosses) with increasing aging duration, and thus an increasing fuzziness or uncertainty of the prediction.

The determination of the optimal database is made by finding a time period which ends at the determined evaluation time point. A search is made for a time period in which a second derivative of the data points/trajectory points does not exceed a predetermined threshold value. Such a time period may be determined by forming a second derivative of the state-of-health trajectory determined up to then, or of the state-of-health curve formed by the data points. The curve of the second derivative is subsequently normalized with respect to the absolute maximum. It may also be provided that the trajectory of the second derivative of the curve of the state of health is first smoothed, for example based on a moving average, in order to suppress numeric noise.

Now, starting from the last data point of the state-of-health trajectory, it is checked whether the second derivative, i.e. the curvature of the past data points, exceeds a certain predetermined threshold value. This is checked data point by data point, starting from the current aging time point into the past. The database is selected from all trajectory points or data points of the state-of-health curve which selected between the data point at which the curvature exceeds the predetermined threshold value and the data point of the current aging time point. It is thereby ensured that the temporal width of the database is optimally adjusted to the trend of the state-of-health trajectory in the region of the most recent trajectory points.

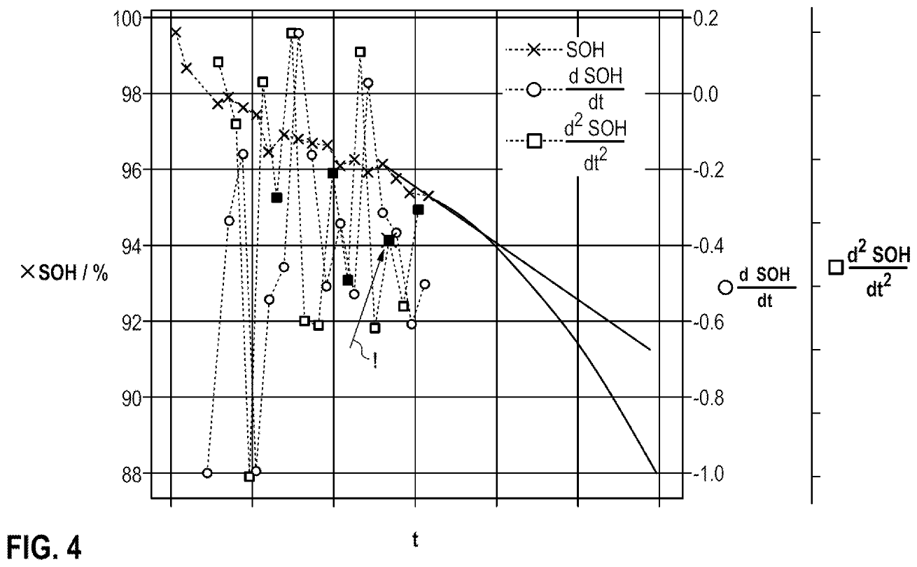

FIG. 4 shows an example of a state-of-health curve with data points (crosses) and their first (circles) and second derivatives (squares). The arrow indicates that the second derivative of the state-of-health curve exceeds the predefined threshold value. By means of the selection of the database in step S4, a section at the end of the state-of-health curve is selected which is sufficiently linear to be able to be used for a naive prediction, i.e. a linear extrapolation of the state-of-health trajectory.

In the depicted exemplary embodiment, the selected database comprises the last five data points of the state-of-health curve. This selection step makes it possible for the database for the prediction to comprise exactly that portion of the state-of-health curve in which the increase is sufficiently flat. This ensures that the model function of the naive prediction adequately describes the behavior of the state-of-health trajectory in the selection domain, and continues as steadily as possible in the extrapolation domain.

In a next step S5, the optimal prediction horizon is selected. For this purpose, two predictions are carried out based on the selected database, until the deviations ASOH of the predicted model values from one another exceed a predetermined limit value. The predictions comprise a first prediction, for example with a model function of a linear extrapolation (naive prediction) based on the database of selected data points. Alternatively, data-driven and generally nonlinear methods may also be used here as an alternative to linear prediction.

A second prediction corresponding to a further model function is carried out based on the slope at the current aging time point and a constant curvature based on the database of selected data points. The constant curvature is calculated as a weighted average or median value of the curvature of the state-of-health trajectory in the selected data domain. For example, the weighting may be selected as a function of the time interval from the current aging time point, so that the more recent values are weighted more strongly than older values.

Based on the average (or the median value) of the curvature and the last slope value of the state-of-health curve of the selected database, i.e., the slope value between the current aging time point and the previously determined data point/trajectory point, the state-of-health curve may be extrapolated. This is depicted, for example in FIG. 4, by the naive first prediction (solid line) and the curvature-based second prediction (dashed curve). It is apparent that the two predictions diverge up to the aging time point at which the predetermined limit value is exceeded. This point in time constitutes the prediction horizon.

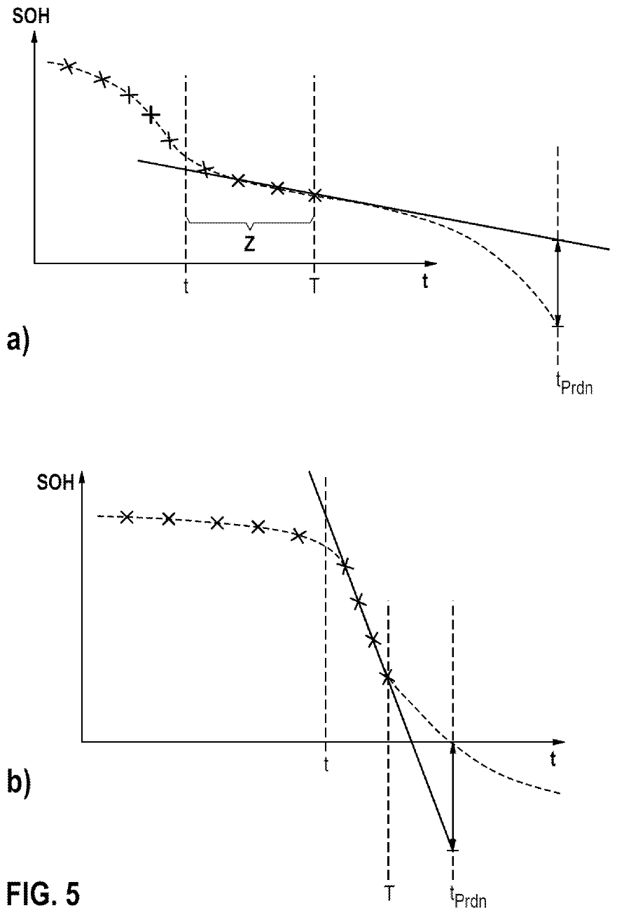

FIGS. 5A and 5B show two examples of predicted curves of the first prediction (solid curve) and the second prediction (dashed curve). It is apparent that that the two curves respectively diverge until a deviation of the predetermined limit value is reached at the point in time t_{Prdn} of the prediction horizon.

To indicate the aging behavior, in step S6, the state of health at the time point of the prediction horizon is now signaled. For this purpose, the state of health may possibly be transmitted back to the respective vehicle 4.

This state of health may be determined from a weighted average value of the naive first prediction of the model function and the curvature-based second prediction of the further model function at the time point t_{Prdn} of the optimal prediction horizon. Thus, depending on the weighting, either the naive or curvature-based prediction is given greater importance with respect to the predicted state of health.

The weightings, which indicate how strongly the linear prediction of the model function is to be weighted and how strongly the prediction of the further model function with constant curvature is to be weighted, may be determined by means of a predetermined weighting model. The weighting model may be data-based and configured and/or trained to determine the weightings based on cumulative or statistical operating features of the relevant vehicle battery which characterize the operation of the vehicle battery over its total operating life (since commissioning), for example, a total Ah throughput, load variables such as the frequency of fast charging events, and the like.

The weighting model may be optimized as a self-learning system via clustering methods based on similarity conditions of the plurality of batteries, and learned and continuously improved over large amounts of data.

The vehicle or battery manufacturer may compare the predicted state of health with its technical specification in order to carry out continuous lifetime monitoring of the vehicle battery. Furthermore, the predicted state of health is relevant for a usage certificate of the battery, as it is associated with the residual value of the vehicle battery.

Furthermore, the degradation behavior of a plurality of vehicle batteries in a fleet may be compared in order to make statements about series dispersion and the aging curve via statistical quantile evaluations. The usage behavior of vehicle batteries from particularly critical quantiles may be optimized via measures for extending the lifetime of the vehicle battery, for example, with the aid of an optimized charging curve or reduced stress factors.

What is claimed is:

1. A method, which is computer-implemented, for determining a predicted state-of-health curve of device batteries in battery-powered machines, the method comprising:
providing, in a central device, data points of one of (i) a state-of-health curve and (ii) a state-of-health trajectory for a device battery, the data points indicating a state of health via an aging time point of the device battery, the one of (i) the state-of-health curve and (ii) the state-of-health trajectory indicating a progression of a state of health of the device battery up to a current state of health;
determining a database of a plurality of data points within a time period which ends at a current aging time point, the database being determined such that a residual between a model function and the data points is minimized by fitting the model function;
extrapolating the plurality of data points of the database by parameterizing the model function; and
determining a predicted state of health using the parameterized model function at a predetermined prediction time point.

2. The method according to claim 1, the determining the database of the plurality of data points further comprising:
selecting a time period starting from a time point at which a second derivative of one of the data points last exceeds a magnitude of a predetermined curvature threshold.

3. The method according to claim 1 further comprising:
predicting, using the state-of-health trajectory, a time point at which a particular state of health is reached based on the model function.

4. The method according to claim 1, wherein at least one of (i) the providing the data points, (ii) the determining the database of the plurality of data points, (iii) the extrapolating the plurality of data points, and (iv) the determining the predicted state of health, is performed by the central device, the central device having a communication link with a plurality of battery-powered machines.

5. The method according to claim 1 further comprising:
determining a prediction horizon as a time point up to which a predetermined prediction certainty exists, the time point being determined as a time point at which a deviation between the model function and a further model function that extrapolates a further predicted curve based on a slope and a curvature of the plurality of data points of the database at a current aging time point, achieves the predetermined prediction certainty.

6. The method according to claim 5, the determining the predicted state of health further comprising:
determining the predicted state of health at the time point of the prediction horizon as a weighted average value of a model value of the model function and a model value of the further model function.

7. The method according to claim 6 further comprising:
determining, using a predetermined weighting model, weightings that indicate (i) an extent to which a model value of the model function is weighted and (ii) an extent to which a model value of the further model function having constant curvature is weighted, the predetermined weighting model being configured to indicate the weightings based on one of cumulative and statistical operating features of the device battery, which characterize operation of the device battery over its total operating life.

8. The method according to claim 5 further comprising:
signaling the predicted state of health at the time point of the prediction horizon.

9. A device for determining a predicted state-of-health curve of device batteries in battery-powered machines, the device being configured to:
provide, in a central device, data points of one of (i) a state-of-health curve and (ii) a state-of-health trajectory for a device battery, the data points indicating a state of health via an aging time point of the device battery, the one of (i) the state-of-health curve and (ii) the state-of-health trajectory indicating a progression of a state of health of the device battery up to a current state of health;
determine a database of a plurality of data points within a time period which ends at a current aging time point, the database being determined such that a residual between a model function and the data points is minimized by fitting the model function;
extrapolate the plurality of data points of the database by parameterizing the model function; and
determine a predicted state of health using the parameterized model function at a predetermined prediction time point.

10. The method according to claim 1, wherein the method is carried out by a computer program that is executed by at least one data processing device.

11. A non-transitory machine-readable storage medium storing instructions for determining a predicted state-of-health curve of device batteries in battery-powered machines, the instructions being configured to, when executed by a least one data processing device, cause the least one data processing device to:
provide, in a central device, data points of one of (i) a state-of-health curve and (ii) a state-of-health trajectory for a device battery, the data points indicating a state of health via an aging time point of the device battery, the one of (i) the state-of-health curve and (ii) the state-of-health trajectory indicating a progression of a state of health of the device battery up to a current state of health;
determine a database of a plurality of data points within a time period which ends at a current aging time point, the database being determined such that a residual between a model function and the data points is minimized by fitting the model function;
extrapolate the plurality of data points of the database by parameterizing the model function; and
determine a predicted state of health using the parameterized model function at a predetermined prediction time point.

12. The device according to claim 9, wherein the battery-powered machines are electrically drivable motor vehicles.

13. The device according to claim 9, wherein the model function is a linear model function.

14. The method according to claim 1, wherein the battery-powered machines are electrically drivable motor vehicles.

15. The method according to claim 1, wherein the model function is a linear model function.

16. The method according to claim 3, wherein the particular state of health is one of (i) an end of life of the device battery and (ii) a remaining lifetime of the device battery.
